(19) United States
(12) Patent Application Publication
(10) Pub. No.: US 2025/0301572 A1
(43) Pub. Date: Sep. 25, 2025

(54) ELECTRICAL CONNECTOR APPARATUS AND METHOD

(71) Applicant: Samtec, Inc., New Albany, IN (US)

(72) Inventor: Thomas A. Hall, III, New Albany, IN (US)

(21) Appl. No.: 19/086,449

(22) Filed: Mar. 21, 2025

Related U.S. Application Data
(60) Provisional application No. 63/568,729, filed on Mar. 22, 2024.

(51) Int. Cl. H05K 1/14; H01R 12/70; H01R 12/71; H01R 12/72; H01R 12/73; H01R 13/621

(52) U.S. Cl. CPC H05K 1/141; H01R 12/7047; H01R 12/716; H01R 12/721; H01R 12/737; H01R 13/621; H05K 2201/042

(57) ABSTRACT

A printed circuit board apparatus and method as described herein. The printed circuit board may couple to one or more connectors. The printed circuit board may define at least a portion of one or more notches. The printed circuit board may include one or more fastener receiving holes. The printed circuit board may include one or more receptacles.

### TECHNICAL FIELD

The present embodiments relate generally to an electrical connector apparatus, or more specifically an electrical connector apparatus having an edge card.

### BACKGROUND

A typical mezzanine connector system may have a stack height required for a particular application. Thus, there is a need to improve the alignment, enhance contact to pad placement, increase stack height flexibility, and/or enhance assembly process.

The present invention is directed at overcoming, or at least improving upon, the disadvantages of the prior art.

### BRIEF DESCRIPTION OF OTHER TECHNICAL FEATURES

U.S. Pat. Nos. 9,374,900; 7,553,182; 8,979,562; 5,085,590; 4,878,856; and 7,338,291 and US Publication Nos. US20160013588 are hereby incorporated by reference in their entireties.

### BRIEF DESCRIPTION OF THE ILLUSTRATIONS

In the drawings, like reference characters generally refer to the same parts throughout the different views. Also, the drawings are not necessarily to scale, emphasis instead generally being placed upon illustrating the principles of the invention.

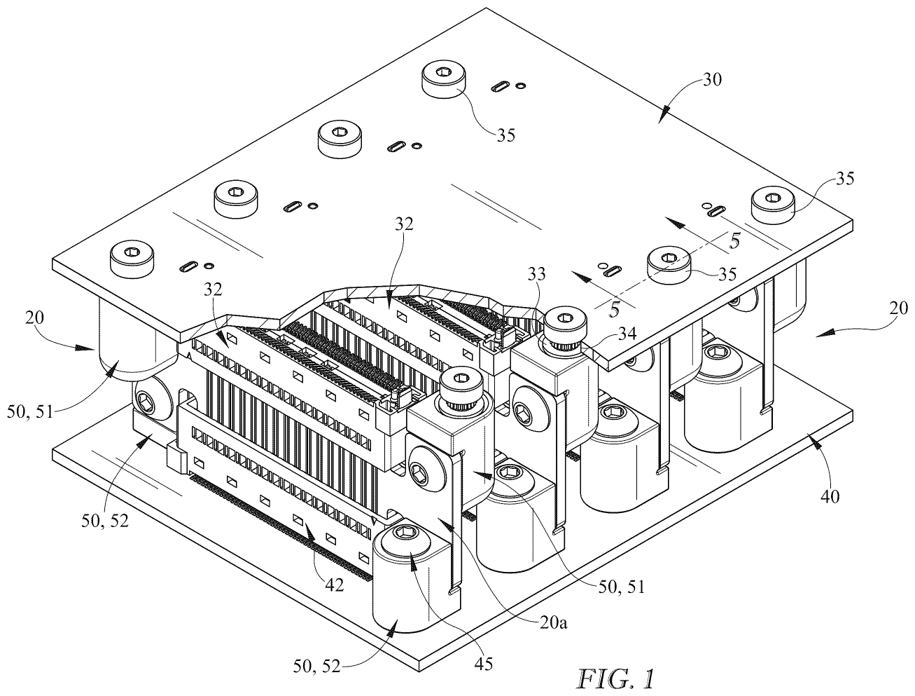

FIG. 1 is a perspective view of one embodiment of a plurality of printed circuit boards arranged between two substantially parallel substrates with corresponding top and bottom connectors.

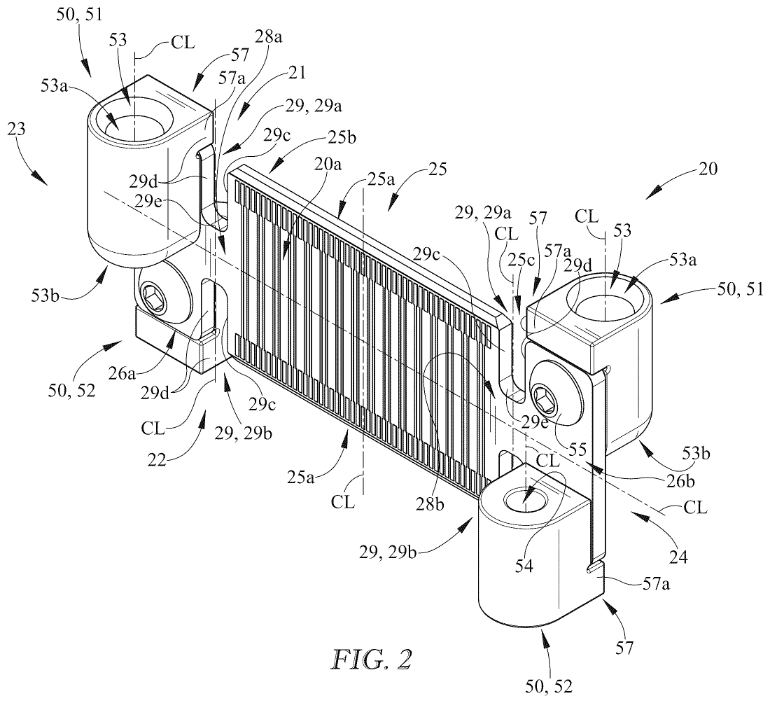

FIG. 2 is a front perspective view of the printed circuit board of FIG. 1, the front perspective view may be the same as the back perspective view.

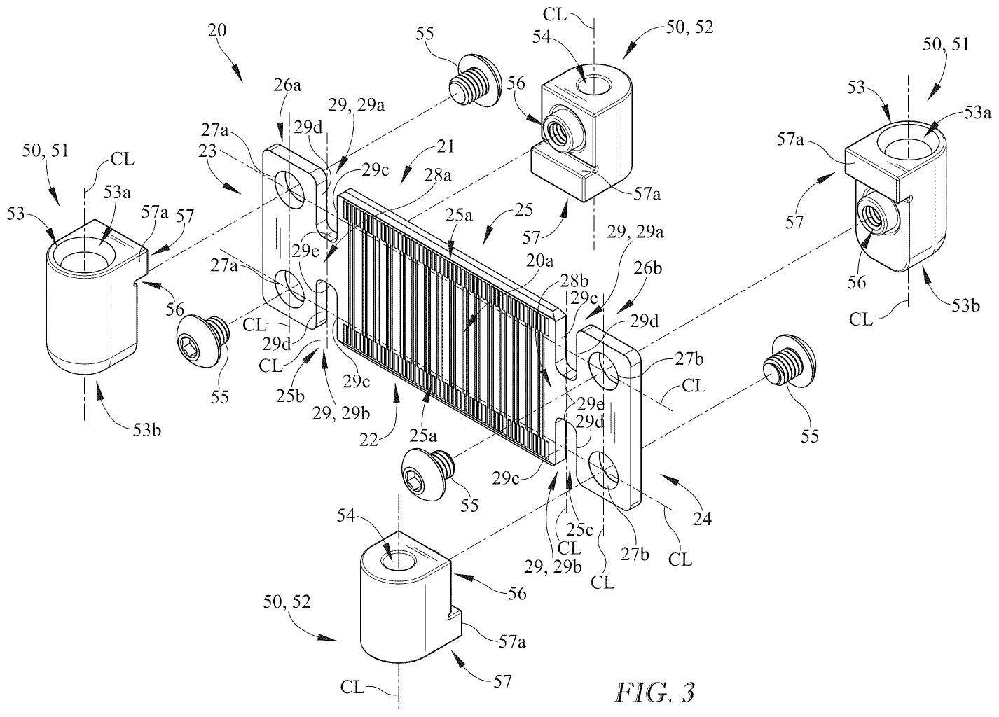

FIG. 3 is an exploded view of the printed circuit board of FIG. 2.

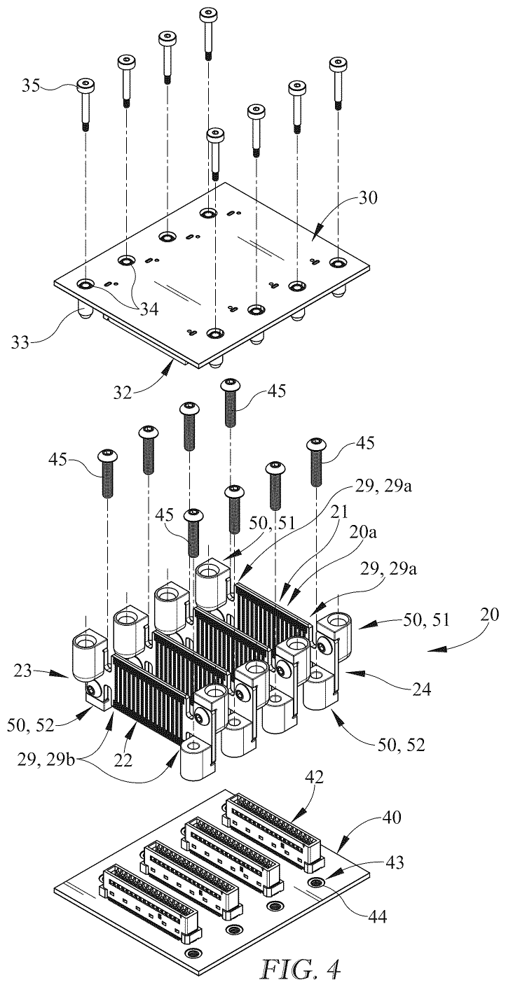

FIG. 4 is a perspective view of the printed circuit boards exploded away from the substrates of FIG. 1.

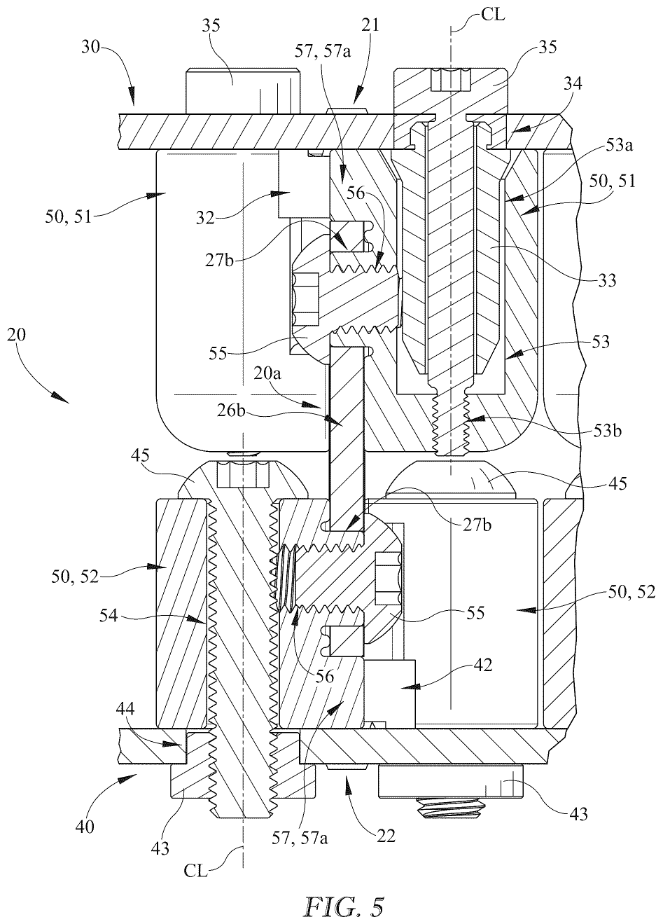

FIG. 5 is a sectional view taken along line 5-5 of FIG. 1.

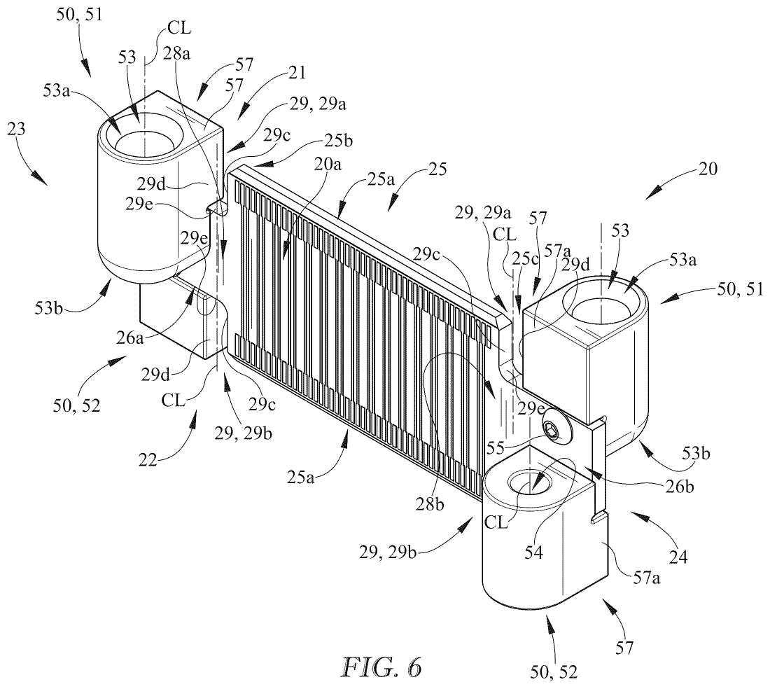

FIG. 6 is a front perspective view of another embodiment of a printed circuit board, the front perspective view may be the same as the back perspective view.

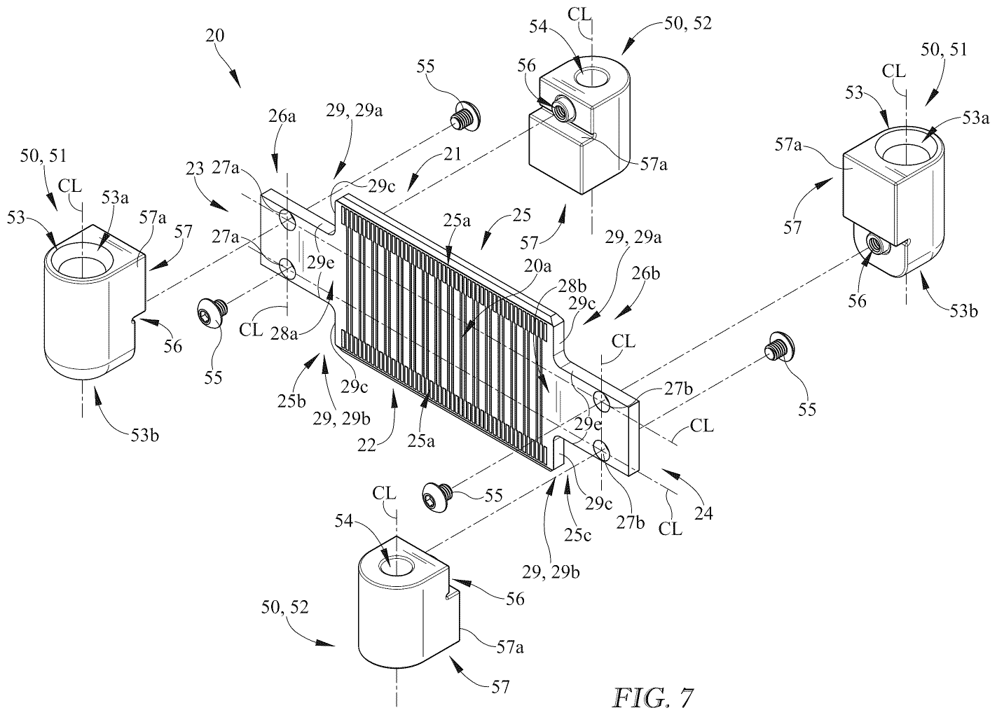

FIG. 7 is an exploded view of the printed circuit board of FIG. 6.

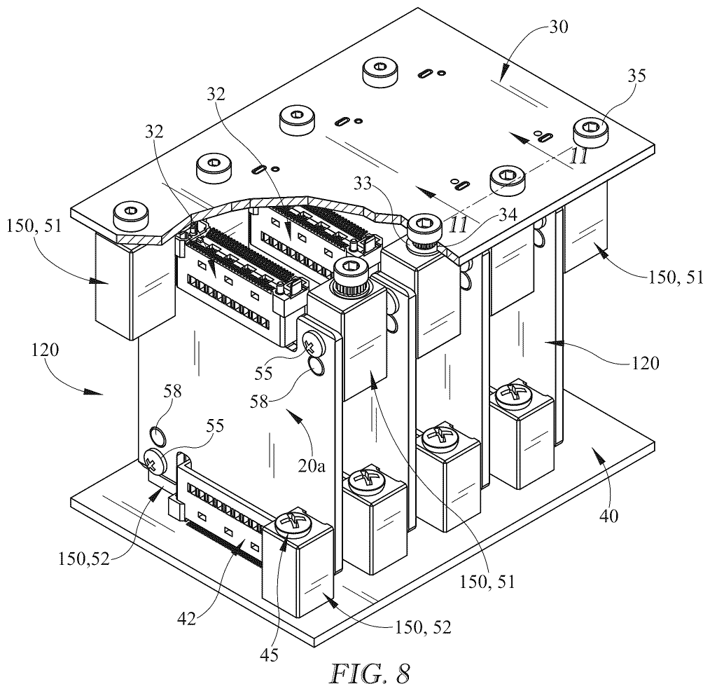

FIG. 8 is a perspective view of one embodiment of a plurality of printed circuit boards arranged between two substantially parallel substrates with corresponding top and bottom connectors.

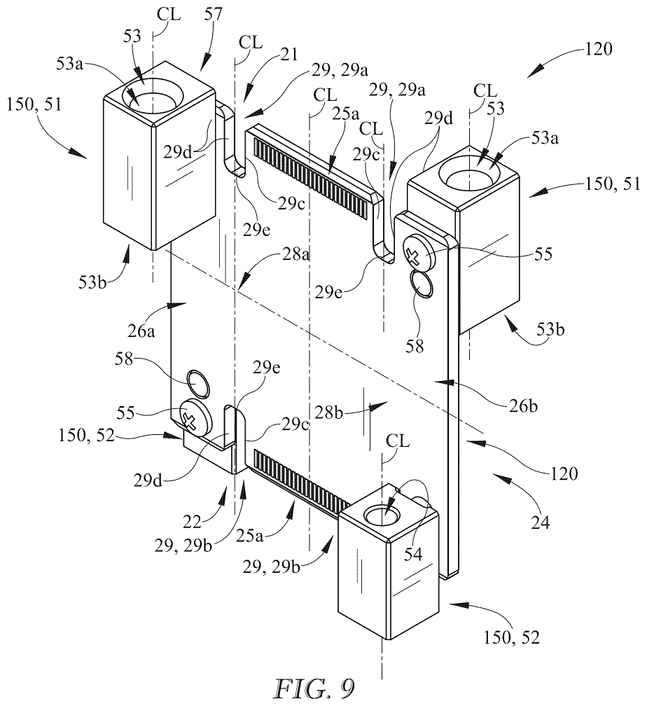

FIG. 9 is a front perspective view of the printed circuit board of FIG. 8, the front perspective view may be the same as the back perspective view.

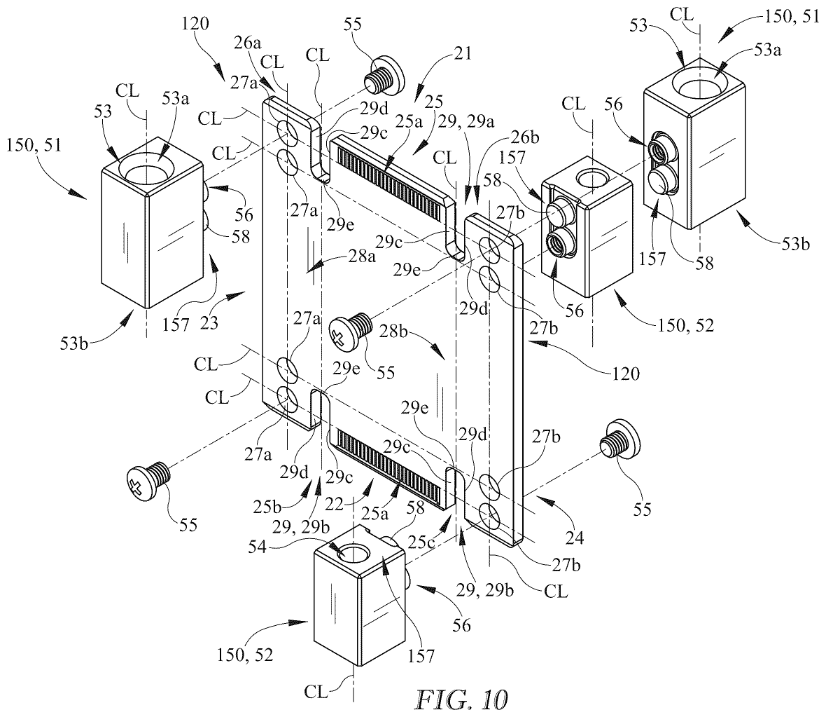

FIG. 10 is an exploded view of the printed circuit board of FIG. 9.

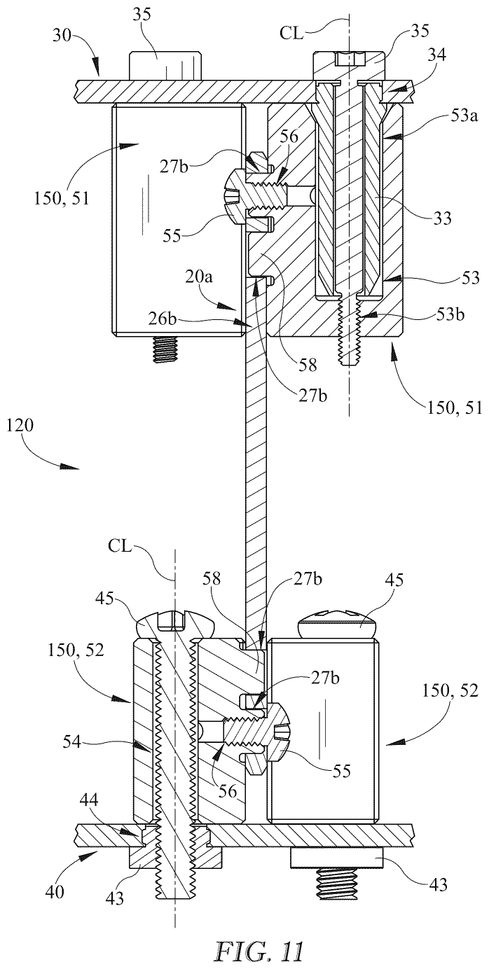

FIG. 11 is a sectional view taken along line 11-11 of FIG. 8.

### DETAILED DESCRIPTION

Embodiments may further be understood with reference to the various Figures. With reference to the Figures, an embodiment provides for one or more printed circuit boards, edge cards, risers 20. The printed circuit board(s) 20 may provide for a board to board assembly in one or more applications (e.g. mezzanine connector system). One or more printed circuit boards 20 may be positioned between or couple two substrates or PCBs 30, 40 (e.g. upper, lower, first, second). The PCBs 30, 40 may include corresponding top and bottom connectors 32, 42, respectively. The PCBs 30 and 40 may be substantially parallel to each other. The PCBs 30, 40 may include one or more alignment pins or posts 33 projecting towards the opposing board, or towards the printed circuit board 20, or portions thereof, when assembled. The pins 33 may project substantially perpendicular from the substrate surface (e.g. 30, 40). The pins 33 may not by aligned in the same plane as the connector. The pins 33 may be in different planes from each other along the board, respectively, and offset from and parallel to the plane (e.g. first) of the connector 32 (e.g. along the length, direction between pins) and/or planar body/housing 20a. As shown for example in the second PCB 30, the pins 33 are in different planes (e.g. second plane, third plane) on opposing sides of the connector 32 (e.g. first plane) and/or planar body 20a. The pin(s) 33 may include an aperture 33a. The PCB(s) 30, 40 may include an aperture or through opening 34, 44 therein. The through aperture/opening 33a, 34 of the pins 33 and boards 30 may be substantially coaxially. The pin 33 may be positioned in the aperture 34 of the second PCB 30. In some embodiments, the PCBs 40 may include a nut 43 (e.g. captive nut, press in nut, threaded). For example, the first PCB 40 may include a threaded nut 43 positioned in one or more apertures 44 therein. The through aperture/opening of the nut 43 and boards 40 may be substantially coaxially. The nut 43 may be positioned in the aperture 44 of the first PCB 40. The threaded nuts 43 and/or apertures 44 may be in in different planes from each other along the board 40, respectively, and offset from and parallel to the plane (e.g. first) of the connector 42 (e.g. along the length, direction between nuts). As shown for example in the first PCB 40, the threaded nuts 43 and apertures 44 are in different planes (e.g. second plane, third plane) on opposing sides of the connector 42 (e.g. first plane).

In some implementations, the printed circuit board 20 may include a substantially planar body or housing 20a. The board 20 or body 20a may include a first major surface that lies substantially in a first plane and a second major surface that lies in another or second plane positioned parallel to the first plane. The board 20 (e.g. middle body portion, first fastener portion, second fastener portion, bridge portion) may include an upper, first, top mating edge 21 and an opposing lower, second, bottom mating edge 22. The board 20 (e.g. first fastener portion, second fastener portion) may include a third edge 23 and opposing fourth edge 24. The third and fourth edges 23, 24 may interconnect the first and second edges 21, 22. The board 20 may include a middle body portion 25. The middle body portion 25 or board 20, or portions thereof, may include one or more electrical conductor pads 25a. A first group of electrical conductor pads 25a may be positioned along the first edge 21 of the board 20 or middle body portion. A second group of electrical conductor pads 25a may be positioned along the second edge 22 of the board 20 or middle body portion. The middle body portion 25, pads 25a, or board 20 may be received within the one or more connectors 32, 42. The board 20 and or middle body portion 25 may include one or more fastener portions 26a, 26b coupled to the middle body portion 25. The fastener portion(s) 26a, 26b may include one or more fastener receiving holes 27a, 27b (e.g. first, second). The fastener portions 26a, 26b may be free from or not include conductor pads on one or more ends. The one or more fastener receiving holes 27a, 27b may position or engage one or more receptacles 50 or hardware, or portions thereof. A first fastener portion 26a may be adjacent the third edge 23. The first fastener portion 26a may include one or more first fastener receiving holes 27a. The one or more first fastener receiving holes 27a may include a pair of first fastener receiving holes along a common centerline in a direction from the first edge to the second edge of the first fastener portion. A second fastener portion 26b may be adjacent the fourth edge 24. The second fastener portion 26b may include one or more second fastener receiving holes 27b. The one or more second fastener receiving holes 27b may include a pair of second fastener receiving holes 27b along a common centerline in a direction from the first edge 21 to the second edge 22 of the second fastener portion 26b. The first and/or second fastener receiving holes 27a, 27b may include a longitudinal axis perpendicular to a direction between the first side 25b and the second side 25c of the middle body portion 25. The fastener portion may be a variety of shapes, sizes, constructions, and quantities. For example, see the different fastener portions compared between FIGS. 3 and 7. The board 20 may include one or more bridge portions, if used, connecting the one or more fastener portions 26a, 26b to the middle body portion 25. A first bridge portion 28a may connect the first fastener portion 26a to the first side 25b of the middle body portion 25. A second bridge portion 28b may connect the second fastener portion 26b to the second side 25c of the middle body portion 25. The bridge portion, if used, may not include any electrical conductor pads. The bridge portion, if used, may be a variety of shapes, sizes, constructions, and quantities.

In some implementations, the printed circuit board 20 and/or receptacles 50 may include or define one or more notches 29. The first edge 21 and/or the second edge 22 may include one or more notches 29. The first edge 21 may include a pair of first or upper notches 29a. The upper notches 29a may be spaced apart from each other. The upper notches 29a may extend from the first edge 21 in a direction toward the second edge 22. The second edge 22 may include a pair of second or lower notches 29b. The lower notches 29b may be spaced apart from each other. The lower notches 29b may extend from the second edge 22 in a direction toward the first edge 21. The notch 29, receptacle 50, or board body 20a may include opposing sides 29c, 29d facing each other connected to an end or bottom wall 29e. The one or more notches 29 (e.g. first, second, receptacle), or portions thereof, may receive the connector 32, 42 (e.g. distal ends along the longitudinal axis or first plane, outer periphery) when assembled. The notches 29 may be positioned between the fastener receiving hole, first/second fastener portion, and/or receptacle 50 and the middle body portion (e.g. side) in some embodiments. For example, one fastener receiving hole 27a, 27b may be defined adjacent the one or more upper notches 29a (e.g. spaced apart notches). For example, one fastener receiving hole 27a, 27b may be defined adjacent the one or more lower notches 29b (e.g. spaced apart notches).

Although the first fastener receiving holes 27a (e.g. upper hole and lower hole, pair) adjacent the third edge or positioned with the first fastener portion are shown along a common centerline, the first fastener receiving holes may not be on a common centerline in some embodiments. Although the second fastener receiving holes 27b (e.g. upper hole and lower hole, pair) adjacent the fourth edge or second fastener portion are shown along a common centerline, the second fastener receiving holes may not be on a common centerline in some embodiments. At least one of the first fastener receiving holes 27a may be on a common centerline with at least one of the second fastener receiving holes 27b. In the one embodiment shown, the first fastener receiving hole 27a and the second fastener receiving hole 27b adjacent the first edge 21 are positioned on a common centerline. Further as shown in the one embodiments, the first fastener receiving hole 27a and the second fastener receiving hole 27b adjacent the second edge 22 are positioned on a common centerline.

Although the fastener receiving hole includes a continuous periphery or is completely closed, the hole may be open or partially closed. For example, the fastener receiving hole could be open or a notch within the periphery of the fastener portion in some embodiments. Further, in some embodiments, the fastener receiving holes may not receive a passive or active latch.

In some implementations, the fastener receiving holes 27a, 27b may be a mirror image with respect to a centerline that perpendicularly intersects the third and fourth edges 23, 24. For example, the first fastener receiving holes 27a and/or the second fastener receiving holes 27b may be a mirror image with respect to a centerline that perpendicularly intersects the third and fourth edges.

In some implementations, the fastener receiving holes may be a mirror image with respect to a centerline that perpendicularly intersects the first and second edges 21, 22. For example, the first fastener receiving holes 27a may be a mirror image of the second fastener receiving holes 27b with respect to a centerline that perpendicularly intersects the first and second edges.

In some implementations, the printed circuit board 20 and/or receptacles 50 may include or define opposing notches 29. The board 20, receptacles 50, and/or notches 29 may be or define opposing notches 29 adjacent the third edge 23 and/or the fourth edge 24. First opposing notches 29a, 29b (e.g. an upper notch 29a within the first edge and a lower notch 29b within the second edge) may be adjacent the third edge 23. Second opposing notches 29a, 29b (e.g. an upper notch 29a within the first edge and a lower notch 29b within the second edge) may be adjacent the fourth edge 24. In some implementations, the first opposing notches 29a, 29b, or portions thereof, may define the first bridge portion 28a, the first side 25b of the middle body portion 25, and/or the first fastener portion 26a, or portions thereof. In some implementations, the second opposing notches 29a, 29b, or portions thereof, may define the second bridge portion 28b, the second side 25c of the middle body portion 25, and/or the second fastener portion 26b, or portions thereof.

In some implementations, the printed circuit board 20 and/or receptacle(s) 50, or portions thereof, may define one or more portions of the one or more notches 29. In some embodiments, the notch 29, or portions thereof, may be defined by the board or body 20a. In some embodiments, the notch 29, or portions thereof, may be defined by the receptacle 50, or portions thereof. In some embodiments, the body 20a and/or receptacle 50 may define one or more portions of the notch (e.g. when printed circuit board is disassembled, when printed circuit board is assembled). In the one embodiment in Figures, the board body 20a defines at least a portion of the notch 29. For example, the board 20 and/or body 20a defines the inwardly facing sides 29c, 29d and the bottom wall 29e of the notch 29. In some embodiments as shown, the notch 29 may be defined by both the board body 20a and the one or more receptacles 50. In the embodiment shown in the FIGS. 1-5 and 8-11, the middle body portion 25 (e.g. first side, second side) may define one side 29c (e.g. inner) of the notch, the fastener portion (e.g. first, second) and/or the receptacle 50, 150 may define another side 29d (e.g. outer) of the notch, and the bridge portion (e.g. top edge, bottom edge) defines the end or bottom wall 29e of the notch 29. In the one embodiment shown in FIGS. 6 and 7, the board body 20a, or portions thereof, and the one or more receptacles 50, or portions thereof, define the one or more portions of the notch 29. As shown in the one embodiment in FIGS. 6 and 7, the middle body portion 25 (e.g. first side, second side) may define one side 29c (e.g. inner) of the notch, the receptacle 50 may define another side 29d (e.g. outer) of the notch, and the bridge portion (e.g. top edge, bottom edge) defines the end or bottom wall 29e of the notch 29. Further, the fastener portion 26a, 26b as shown in FIG. 7 may not define the side wall 29d of the notch 29. The receptacle 50, 150 may vary (e.g. lengthen, widen, shorten, increase, decrease) one or more dimensions (e.g. direction from first edge to second edge, direction from third edge to fourth edge, direction between opposing surfaces of the planar body) of the notch (e.g. side, bottom), or portions thereof, defined by the body 20a or printed circuit board. The opposing sides/walls 29d, 29c, 29e of the notch (e.g. defined by the receptacle and/or body) do not have to be the same width and/or length. Although not shown, the receptacle may define more than one side or portion, such as a side and bottom wall of the notch. Further, the receptacle may define the entire notch in some embodiments.

In some implementations, two or more notches 29 may be positioned parallel to each other. The spaced apart upper notches 29a may be positioned parallel to each other. The spaced apart lower notches 29b may be positioned parallel to each other. In some embodiments, at least one upper notch 29a may be positioned parallel to at least one lower notch 29b or extend long a common first centerline. For example, the first opposing notches 29a, 29b and/or second opposing notches 29a, 29b may be positioned parallel to each other, respectively. The first opposing notches 29a, 29b may extend along a common centerline (e.g. first). The second opposing notches 29a, 29b may extend along a common centerline (e.g. second). In some embodiments as shown, the first and second centerline are parallel to each other.

In some implementations, the printed circuit board 20 or body 20a (e.g. notches, holes) may be symmetrical with respect to a centerline that perpendicularly intersects both the third and fourth edges 23, 24. In some embodiments, the printed circuit board 20 or body 20a (e.g. notches, holes) may be symmetrical with respect to a centerline that perpendicularly intersects both the first and second edges 21, 22.

In some implementations, the fastener receiving holes 27a may be described as being adjacent the first opposing notches 29a, 29b. For example, the first fastener receiving holes 27a are adjacent the first opposing notches 29a, 29b. For example, the second fastener receiving holes 27b are adjacent the second opposing notches 29a, 29b.

In some implementations, the printed circuit board 20 may include one or more receptacles 50. The receptacle(s) 50 may engage one or more fastener receiving holes. The receptacles may engage one or more fastener portions. The one or more receptacles 50 may engage at least one of the first fastener receiving hole 27a and/or the second fastener receiving hole 27b. The receptacle 50 may include one or more apertures 53, 54. The aperture may include a longitudinal axis (e.g. first, second). The receptacle may include a threaded aperture 56 having a third longitudinal axis substantially perpendicular to the longitudinal axis (e.g. first, second) of the receptacle aperture 53, 54 and/or planar body 20a. The threaded aperture 56 threadably engages a third fastener 55 to engage the receptacle 50 to the printed circuit board 20, or remaining portions thereof.

In some implementations, the receptacles 50 may be the same. The same receptacles 50 (e.g. first, 51) may be positioned adjacent the first edge 21 in some embodiments. The receptacles 50 may include a first receptacle 51. One first receptacle 51 (e.g. upper) may engage the first fastener receiving hole 27a adjacent the first edge 21 and another first receptacle 51 may engage the second fastener receiving hole 27b adjacent the first edge 21. The first receptacle 51 may include the first aperture 53 receiving the alignment pin 33 and/or fastener 35. The first receptacle 51 may be adjacent the second PCB 30. The first edge 21 of the printed circuit board 20 or middle body portion 25 may be received within the connector 32. The first aperture 53 may include a first portion 53a with a proximal opening receiving a pin 33 and a fastener 35 (e.g. threaded) and a second portion 53b receiving the fastener 35. The pin 33 includes a through opening 33a receiving the fastener 35 therethrough. The second portion 53b is threaded to threadably engage the fastener 35. Similar receptacles (e.g. second) may be positioned adjacent the second edge 22 in some embodiments. The receptacles 50 may include a second receptacle 52. One second receptacle 52 (e.g. upper) may engage the first fastener receiving hole 27a adjacent the second edge 22 and another second receptacle 52 may engage the second fastener receiving hole 27b adjacent the second edge 22. The second receptacle 52 may include the second aperture 54 receiving a fastener 45. The second receptacle 52 may be adjacent the first PCB 40. The second aperture 54 may receive the fastener 45 therethrough to engage the nut 43 in the aperture 44 of the first PCB 40. The fastener 45 may threadably engage the nut 43.

In some implementations, the receptacles 50 may be different. The first receptacle 51 may be different from the second receptacle 52. For example, in some embodiments, the first receptacle 51 may include a threaded first aperture or portion 53b. The second receptacle 52 may include a second aperture 54. The second aperture 54 may not include a threaded portion in some embodiments. A kit may include the first receptacle(s), or portions thereof, and/or the second receptacle(s), or portions thereof. The first receptable(s) 51 and/or kit, or portions thereof, may include the pin(s) 33, the fastener 35, and/or the third fastener(s) 55. The second receptable(s) 52 and/or kit, or portions thereof, may include the fastener 45, nut 43, and/or the third fastener(s) 55.

In some implementations, the receptacle 50 and/or printed circuit board 20 may include one or more stopping mechanisms 57. The stopping mechanisms 57 may be one or more vertical stops and/or one or more rotational stops. The vertical stop may reduce or prevent vertical or longitudinal movement between the receptacle 50 (e.g. first, second) and the printed circuit board 20 or body 20a. The stop 57 may position the body 20a or printed circuit board 20 from PCBs 30, 40. The rotational stop may reduce or prevent rotational/pivoting movement between the receptacle 50 (e.g. first, second) and the printed circuit board 20 or body 20a. In the one embodiment shown in the Figures, the receptacle 50 (e.g. first, second) includes at least one stopping mechanism 57. The stopping mechanism 57, if used, may include both the vertical stop and the rotational stop. The stopping mechanism stops relative movement of the receptacle 50 to the body 20a in both the vertical direction (e.g. axial, longitudinal) and rotational direction (e.g. about the threaded aperture 56 or third fastener 55). However, it should be understood that the stopping mechanism may limit travel only in the vertical direction and other embodiments may be only in the rotational direction. As shown, the stopping mechanism 57 may be at least a flange or tab 57a projecting from a side or outer periphery of the receptacle. The flange 57a may project substantially perpendicular to the aperture 53, 54 or longitudinal axis therein. The flange 57a of the receptacle 50 may abut or engage one or more edges/surfaces (e.g. top edge 21, bottom edge 22) of the printed circuit board 20 or body 20a, or portions thereof, (e.g. first fastener portion, second fastener portion, first bridge portion, second bridge portion). When assembled, the flanges 57a of the first receptacle 51 and the second receptacle 52 are positioned on and/or engage opposing edges (e.g. first, second) of the printed circuit board.

In some implementations, a kit for the printed circuit board 20 may include a plurality of pins 33, receptacles 50, first receptacles 51, and/or second receptacles 52. The first receptacles 51 may receive the plurality of pins 33. The kit may include a plurality of fasteners (e.g. first, second, third, fourth, etc.). A first fastener 35 may be configured to extend through the pin 33 (e.g. aperture 33a) and/or first aperture 53. The first fastener 35 may threadably engage the first aperture 53 and/or second portion 53b of the first receptacle 51. The first fastener 35 may couple the second PCB 30 to the printed circuit board 20 and/or first receptacle 51 when the middle body portion 25 and/or first edge 21 engages the connector 32. In some embodiments, the first receptacle(s) 51 may include a threaded aperture 56 substantially perpendicular to the first aperture 53. The kit may include a fastener(s) (e.g. third fasteners 55) threadably engaging the threaded aperture 56 of the first receptacle 51 to couple the planar body 20a with the first receptacle 51. The kit may include a second receptacle(s) 52. The second receptacle 52 may be different from the first receptacle 51 in some embodiments. A second fastener 45 may be configured to extend through the second receptacle 52 and/or second aperture 54. The second fastener 45 may extend through the second receptacle 52 (e.g. second aperture 54) and threadably engage the nut 43 within the aperture 44 of the first PCB 40. The second fastener 45 may couple the first PCB 40 to the printed circuit board 20 and/or second receptacle 52 when the middle body portion 25 and/or second edge 22 engages the connector 42. In some embodiments, the second receptacle(s) 52 may include a threaded aperture 56 substantially perpendicular to the second aperture 54. The kit may include a fastener(s) (e.g. third fasteners 55) threadably engaging the threaded aperture 56 of the second receptacle 52 to couple the planar body 20a with the second receptacle 52.

In some implementations, the longitudinal axis of the receptacles 50 and/or apertures 53, 54 may be parallel to the planar body 20a. The first longitudinal axis of the first receptacle 51 or first aperture 53 and/or the second longitudinal axis of the second receptacle 52 or second aperture 54 may be parallel to the first plane of the planar body (e.g. plane of first major surface, plane of second major surface). The first longitudinal axis may be parallel to the second longitudinal axis. The first and/or second longitudinal axis may extend in a direction from the first edge to the second edge. The first longitudinal axis of the first receptacle 51 positioned on the first fastener portion 26a and the second longitudinal axis of the second receptacle 52 positioned on the first fastener portion 26a are positioned in different planes and/or parallel to the first plane of the planar body 20a (e.g. plane of first major surface, plane of second major surface). The first longitudinal axis of the first receptacle 51 positioned on the second fastener portion 26b and the second longitudinal axis of the second receptacle 52 positioned on the second fastener portion 26b are positioned in different planes and/or parallel to the first plane of the planar body 20a (e.g. plane of first major surface, plane of second major surface). The first receptacle 51 (e.g. upper) positioned on the second fastener portion 26b is positioned on one side/surface of the planar body 20a and/or positioned adjacent the first major surface and the second receptacle 52 (e.g. lower) positioned on the second fastener portion 26b is positioned on the other/opposing side/surface of the planar body 20a and/or positioned adjacent the second major surface. The first receptacle 51 (e.g. upper) positioned on the first fastener portion 26a is positioned on one side/surface of the planar body 20a and/or positioned adjacent the first major surface and the second receptacle 52 (e.g. lower) positioned on the first fastener portion 26a is positioned on the other/opposing side/surface of the planar body 20a and/or positioned adjacent the second major surface. The receptacles 50 (e.g. first, second) and corresponding longitudinal axis (e.g. first, second) on one side of the planar body 20a are in the same plane and parallel to each other and/or the receptacles 50 (e.g. first, second) and corresponding longitudinal axis (e.g. first, second) on the other side of the planar body 20a are in the same plane and parallel to each other.

In some implementations, the assembling of the mezzanine connector system may include providing a first PCB 40 having at least one first connector housing 42 extending along a first plane and a first pair of apertures 44 in different planes offset and parallel to the first plane. In some embodiments, the assembling of the mezzanine connector system may include one or more kits. The method may include providing a second PCB 30 having at least one second connector housing 32 extending along the first plane and a first pair of pins 33 in different planes offset and parallel to the first plane. The method may include coupling the first PCB 40 to the second PCB 30 with a printed circuit board 20 having opposing receptacles 50 configured to receive the first pair of pins 33 and engage the first pair of apertures 44 in one or more planes, respectively. The opposing receptacles 50 may be the first receptacles 51 opposing the second receptacles 52. In some embodiments, the opposing receptacles 50 may stop the axial movement of the printed circuit board 20 and/or the second PCB 30 and/or first PCB 40 when coupling. Stopping the axial movement may set the edge card distance or insertion within one or more connectors. In some embodiments, the method may include engaging the first pair of pins 33 to the receptacles 50 (e.g. first receptacles) before the printed circuit board 20 (e.g. middle body portion) engages at least one second connector 32. In various embodiments, the method may include coupling the printed circuit board 20 to the first PCB 40 (e.g. via the fastener 45, nut 43, second receptacle 52, connector 42) and subsequently coupling the second PCB 30 to the printed circuit board 20 (e.g. via the fastener 35, pin 33, first receptacle 51, connector 32). The method may include threadably engaging the first pair of pins 33 or PCB 30 to the receptacles 50 (e.g. first) (e.g. via fastener 35) and the first pair of receptacles 50 (e.g. second) to the apertures 44 and/or PCB 40 (e.g. via fastener 45 and/or nut 43) in the same direction from the second PCB 30 to the first PCB 40.

In some implementations, the printed circuit board 120 and/or receptacle 150 (e.g. first, second) may include one or more pins 58. As shown in FIGS. 8-11, the pin 58 may engage one or more of the fastener receiving holes (e.g. first, second) and/or fastener portions (e.g. first, second). The pin 58 may be on the same side of the threaded aperture 56. The axis of the pin 58 and the threaded aperture 56 may be parallel to each other. The axis of the pin(s) 58 and threaded aperture(s) 56 may be positioned along a common centerline. The pin 58 may be positioned between the threaded aperture 56 and the outer facing wall/side (e.g. having the aperture 53, 54) and/or first edge 21/second edge 22, respectively. The pin 58 may project in a substantially perpendicular direction to the plane of the body 20a and/or aperture 53, 54. In some embodiments, the pin 58 may be the stopping mechanism 157 (e.g. rotational, axial) to provide alignment and/or reduce movement of the receptacle relative to the body of the printed circuit board 120. Although the pin 58 is shown as a circular pin, it should be understood that the pin may be a variety of shapes, sizes, quantities, and constructions. As shown in FIGS. 8-11, the fastener portion (e.g. first, second) may include a pair of fastener receiving holes adjacent the first edge 21 and/or second edge 22. The fastener receiving holes (e.g. first, second, pair(s)) of a respective fastener portion (e.g. first, second) may be positioned on a common centerline.

In some implementations, the receptacles 50, 150 (e.g. first, second) may space or position the planar body 20a or printed circuit board 20 from the PCBs (e.g. 30, 40). The receptacles 50, 150 may extend/project (e.g. outwardly) from or beyond the first edge 21 and/or second edge 22 for one or more distances. The receptacles may abut/engage the PCBs and one or more portions of the printed circuit board 20 or body 20a. This may position the middle body portion 25 and/or printed circuit board 20, 120 relative to the connector 32, 42.

In some implementations, the printed circuit board 20, 120 and/or planar body 20a may be a variety of different heights or dimensions between the two PCBs 30, 40. The distance between the first edge 21 and second edge and/or opposing electrical conductor pads 25a may be a variety of distances. For example as shown in FIGS. 1 and 8, the board 20 has a height (e.g. first) smaller than the height (e.g. second) of board 120.

In some embodiments, a printed circuit board may include a first major surface that lies substantially in a first plane. In various embodiments, the printed circuit board may include a second major surface that lies substantially in a second plane positioned parallel to the first plane. In some embodiments, the printed circuit board may include a first edge and/or an opposed second edge. In various embodiments, the printed circuit board may include a third edge and an opposed fourth edge. In some embodiments, the printed circuit board may include at least two spaced apart first notches that each extend from the first edge in a direction toward the second edge. In various embodiments, the printed circuit board may include at least two spaced apart second notches that each may extend from the second edge in a direction toward the first edge. In some embodiments, the printed circuit board may include at least one first fastener receiving hole defined adjacent to one of the at least two spaced apart first notches. In various embodiments, the printed circuit board may include at least one second fastener receiving hole defined adjacent to one of the at least two spaced apart second notches.

In addition, in some embodiments, at least two spaced apart first notches may be each positioned parallel to one another. In various embodiments, at least two spaced apart second notches may be each positioned parallel to one another. In some embodiments, one of at least two spaced apart first notches and one of the at least two spaced apart second notches both extend along a common first centerline. In various embodiments, one of at least two spaced apart first notches and one of at least two spaced apart second notches both extend along a first common centerline and another one of at least two spaced apart first notches and another one of at least two spaced apart second notches both extend along a second common centerline. In some embodiments, the first common centerline and the second common centerline may extend parallel to one another. In various embodiments, the printed circuit board may include a first group of electrical conductor pads positioned along the first edge. In some embodiments, the printed circuit board may include a second group of electrical conductor pads positioned along the second edge. In various embodiments, the first fastener receiving hole and the second fastener receiving hole may line on a common centerline. In some embodiments, at least one of the first fastener receiving hole and/or the second fastener receiving hole are completely closed. In various embodiments, the first fastener receiving hole and the second fastener receiving hole do not receive a passive or active latch. In some embodiments, the printed circuit board may be symmetrical with respect to a centerline that perpendicularly intersects both the third and fourth edges. In various embodiments, the printed circuit board may be symmetrical with respect to a centerline that perpendicularly intersects both the first and second edges. In some embodiments, the printed circuit board may include at least one third fastener receiving hole defined adjacent to one of the at least two spaced apart first notches. In various embodiments, the first fastener receiving hole and the third fastener receiving hole may be positioned on the same side of the at least two spaced apart first notches. In some embodiments, the first fastener receiving hole and the third fastener receiving hole may line on a common centerline. In various embodiments, the printed circuit board may include at least one fourth fastener receiving hole defined adjacent to one of at least two spaced apart second notches. In some embodiments, the second fastener receiving hole and the fourth fastener receiving hole may be positioned on the same side of at least two spaced apart second notches. In various embodiments, the second fastener receiving hole and the fourth fastener receiving hole may line on a common centerline. In some embodiments, the printed circuit board may include at least one third fastener receiving hole defined adjacent to one of at least two spaced apart first notches and at least one fourth fastener receiving hole defined adjacent to one of at least two spaced apart second notches. In various embodiments, the third and fourth fastener receiving holes may line on a common centerline. In some embodiments, the first fastener receiving holes and/or the second fastener receiving holes and the third fastener receiving holes and/or the fourth fastener receiving holes may be mirror images with respect to a centerline that perpendicularly intersects both the third and fourth edges. In various embodiments, the first/third fastener receiving holes and the second/fourth fastener receiving holes may be mirror images with respect to a centerline that perpendicularly intersects both the first and second edges. In some embodiments, the printed circuit board may include one or more receptacles engaging at least one of the first fastener receiving hole and/or the second fastener receiving hole. In various embodiments, the printed circuit board may include a PCB having at least one connector and at least one alignment post, wherein the one or more receptacles receive at least one alignment post and at least one connector receives the first edge between the at least two spaced apart first notches. In some embodiments, a first receptacle of the one or more receptacles may engage at least one first fastener receiving hole and a second receptacle of the one or more receptacles may engage at least one second fastener receiving hole. In some embodiments, a longitudinal axis of the first receptacle may be parallel to a longitudinal axis of the second receptacle. In various embodiments, the longitudinal axis of the first receptacle and the longitudinal axis of the second receptacle may be positioned in different planes parallel to both the first plane and the second plane. In some embodiments, the first receptacle may be positioned adjacent the first major surface and the second receptacle may be positioned adjacent the second major surface.

In some embodiments, a printed circuit board may include a planar body having a middle body portion, a first fastener portion, and/or a second fastener portion. In various embodiments, the planar body may include a first edge and an opposed second edge. In some embodiments, the first fastener portion may include one or more first fastener receiving holes. In various embodiments, the second fastener portion may include one or more second fastener receiving holes. In some embodiments, the printed circuit board may include a first bridge portion may connect the first fastener portion to a first side of the middle body portion defined by first opposing notches. In various embodiments, the printed circuit board may include a second bridge portion connecting the second fastener portion to a second side opposing the first side of the middle body portion defined by second opposing notches.

In addition, in some embodiments, each one of the middle body portion, the first fastener portion, and the second fastener portion may include the first edge and the opposed second edge. In various embodiments, only the middle body portion of the printed circuit board may include electrical conductor pads. In some embodiments, the first edge of the middle body portion may include a first group of electrical conductor pads and the second edge of the middle body portion may include a second group of electrical conductor pads opposite the first group of electrical conductor pads. In some embodiments, the one or more first fastener receiving holes and the one or more second fastener receiving holes may include a longitudinal axis perpendicular to a direction between the first side and the second side of the middle body portion. In various embodiments, the one or more first fastener receiving holes may include a pair of first fastener receiving holes extending along a common centerline in a direction from the first edge to the second edge of the first fastener portion. In some embodiments, the one or more second fastener receiving holes may include a pair of second fastener receiving holes extending along a common centerline in a direction from the first edge to the second edge of the second fastener portion. In some embodiments, the printed circuit board may include one or more first receptacles engaging the one or more first fastener receiving holes, wherein a longitudinal axis of the one or more first receptacles may be in a direction from the first edge to the second edge. In various embodiments, the printed circuit board may include one or more second receptacles engaging the one or more second fastener receiving holes, wherein a longitudinal axis of the one or more second receptacles may be in a direction from the first edge to the second edge. In some embodiments, a first receptacle may engage one of the one or more first fastener receiving holes adjacent the first edge and a second receptacle may engage another one of the one or more first fastener receiving holes adjacent the second edge. In various embodiments, the first receptacle and the second receptacle may be on opposing surfaces of the planar body. In some embodiments, the printed circuit board may include at least one of a first printed circuit board and/or a second printed circuit board, wherein the first printed circuit board and/or the second printed circuit board may include a connector receiving the middle body portion. In some embodiments, the first notch and the second notch adjacent the first edge may receive a housing of the connector therein. In various embodiments, the first printed circuit board may include a pair of pins in different planes parallel to and offset from a plane of the planar body.

In some embodiments, a method of assembling a mezzanine connector system may include the step of providing a first PCB having at least one first connector housing extending along a first plane and a first pair of apertures in different planes offset and parallel to the first plane. In various embodiments, the method may include providing a second PCB having at least one second connector housing extending along the first plane and a first pair of pins in different planes offset and parallel to the first plane. In some embodiments, the method may include coupling the first PCB to the second PCB with a printed circuit board having opposing receptacles configured to receive the first pair of pins and engage the first pair of apertures, respectively.

In addition, in some embodiments, at least one of the opposing receptacles stop axial movement of at least one of the printed circuit board and/or the second PCB when coupling. In various embodiments, the method may include engaging the first pair of pins to the receptacles before the printed circuit board engages at least one second connector. In some embodiments, the method may include coupling the printed circuit board to the first PCB and subsequently coupling the second PCB to the printed circuit board. In various embodiments, the method may include threadably engaging the first pair of pins to the receptacles and the first pair of apertures to the receptacles in the same direction from the second PCB to the first PCB. In some embodiments, the printed circuit board may include a middle body portion having a first group of electrical conductor pads along a first edge and a second group of electrical conductor pads along a second edge opposite the first edge, a first bridge portion connecting a first fastener portion to a first side of the middle body portion defined by first opposing notches, a second bridge portion connecting a second fastener portion to a second side opposing the first side of the middle body portion defined by second opposing notches, wherein the first fastener portion includes the receptacles, and/or wherein the second fastener portion includes the receptacles. In various embodiments, the printed circuit board may include a middle body portion having a first group of electrical conductor pads along a first edge and a second group of electrical conductor pads along a second edge opposite the first edge, a first bridge portion connecting a first fastener portion to a first side of the middle body portion, a second bridge portion connecting a second fastener portion to a second side opposing the first side of the middle body portion, wherein the first fastener portion includes the receptacles coupled thereto, wherein the second fastener portion includes the receptacles coupled thereto, and/or wherein the first bridge portion, the receptacles, and the first side of the middle body portion define first opposing notches and wherein the second bridge portion, the receptacles, and the second side of the middle body portion define second opposing notches. In various embodiments, the receptacles positioned on the first fastener portion may be in different planes and parallel to the first plane and the receptacles positioned on the second fastener portion are in different planes and parallel to the first plane.

In some embodiments, a printed circuit board kit may include a plurality of first receptacles configured to couple to a printed circuit board. In various embodiments, the kit may include a plurality of second receptacles configured to couple to the printed circuit board. In some embodiments, the plurality of first receptacles may be different than the plurality of second receptacles.

In addition, in some embodiments, the plurality of first receptacles may include a threaded aperture therein. In various embodiments, the plurality of second receptables may include a through aperture.

In some embodiments, a kit for a printed circuit board may include a plurality of pins. In various embodiments, the kit may include a plurality of first receptacles configured to receive the plurality of pins.

In addition, in some embodiments, the kit may include a plurality of first fasteners configured to extend through the plurality of pins and threadably engage a first aperture of the plurality of first receptacles. In various embodiments, the plurality of first receptacles may include a threaded aperture perpendicular to the first aperture. In some embodiments, the kit may include a plurality of second fasteners threadably engaging the threaded aperture of the plurality of first receptacles. In various embodiments, the plurality of first receptacles may include at least one of a vertical stop and/or rotational stop. In some embodiments, the kit may include a plurality of second receptacles different from the plurality of first receptacles. In various embodiments, the kit may include a plurality of second fasteners configured to extend through a second aperture of the plurality of second receptacles and engage a threaded nut. In some embodiments, the plurality of second receptacles may include a threaded aperture perpendicular to the second aperture. In various embodiments, the plurality of second receptacles may include at least one of a vertical stop and/or rotational stop.

In some embodiments, a printed circuit board may include a planar body having a middle body portion, a first fastener portion, and/or a second fastener portion, and wherein the planar body includes a first edge and an opposed second edge. In various embodiments, the first fastener portion may include one or more first fastener receiving holes. In some embodiments, the second fastener portion may include one or more second fastener receiving holes. In various embodiments, the printed circuit board may include a first bridge portion connecting the first fastener portion to a first side of the middle body portion. In some embodiments, the printed circuit board may include a second bridge portion connecting the second fastener portion to a second side opposing the first side of the middle body portion. In various embodiments, the first fastener portion may include a plurality of first receptacles coupled to the one or more first fastener receiving holes. In some embodiments, the second fastener portion may include a plurality of second receptacles coupled to the one or more second fastener receiving holes. In various embodiments, the first bridge portion, the plurality of first receptacles, and/or the first side of the middle body portion may define first opposing notches. In some embodiments, the second bridge portion, the plurality of second receptacles, and/or the second side of the middle body portion define second opposing notches.

In addition, in some embodiments, each one of the middle body portion, the first fastener portion and the second fastener portion includes the first edge and the opposed second edge. In various embodiments, only the middle body portion of the printed circuit board may include electrical conductor pads, wherein the first edge of the middle body portion includes a first group of electrical conductor pads and the second edge of the middle body portion includes a second group of electrical conductor pads opposite the first group of electrical conductor pads. In some embodiments, the one or more first fastener receiving holes and the one or more second fastener receiving holes may include a longitudinal axis perpendicular to a direction between the first side and the second side of the middle body portion. In various embodiments, the one or more first fastener receiving holes may include a pair of first fastener receiving holes extending along a common centerline in a direction from the first edge to the second edge of the first fastener portion. In some embodiments, the one or more second fastener receiving holes may include a pair of second fastener receiving holes along a common centerline in a direction from the first edge to the second edge of the second fastener portion. In various embodiments, a longitudinal axis of the plurality of first receptacles may be in a direction from the first edge to the second edge. In some embodiments, a longitudinal axis of the plurality of second receptacles may be in a direction from the first edge to the second edge. In various embodiments, an upper receptacle of the plurality of first receptacles may engage one of the one or more first fastener receiving holes adjacent the first edge and a lower receptacle of the plurality of second receptacles may engage another one of the one or more first fastener receiving holes adjacent the second edge. In some embodiments, the upper receptacle and the lower receptacle may be on opposing surfaces of the planar body. In various embodiments, the printed circuit board may include at least one of a first printed circuit board and/or a second printed circuit board, wherein the first printed circuit board and/or the second printed circuit board may include a connector receiving the middle body portion. In some embodiments, the first opposing notch and the second opposing notch adjacent the first edge may receive a housing of the connector therein. In various embodiments, the second printed circuit board may include a pair of pins in different planes parallel to and offset from a plane of the planar body. In some embodiments, the plurality of first receptacles may define at least a side of the first opposing notch opposite the first side of the middle body portion. In various embodiments, the first bridge portion may define a bottom wall of the first opposing notch.

While several embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, embodiments may be practiced otherwise than as specifically described and claimed. Embodiments of the present disclosure are directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

It is to be understood that the embodiments are not limited in its application to the details of construction and the arrangement of components set forth in the description or illustrated in the drawings. The invention is capable of other embodiments and of being practiced or of being carried out in various ways. Unless limited otherwise, the terms “connected,” “coupled,” “in communication with,” and “mounted,” and variations thereof herein are used broadly and encompass direct and indirect connections, couplings, and mountings. In addition, the terms “connected” and “coupled” and variations thereof are not restricted to physical or mechanical connections or couplings.

The foregoing description of several embodiments of the invention has been presented for purposes of illustration. It is not intended to be exhaustive or to limit the invention to the precise steps and/or forms disclosed, and obviously many modifications and variations are possible in light of the above teaching.

1. A printed circuit board comprising:
a first major surface that lies substantially in a first plane;
a second major surface that lies substantially in a second plane positioned parallel to the first plane;
a first edge and an opposed second edge;
a third edge and an opposed fourth edge;
at least two spaced apart first notches that each extend from the first edge in a direction toward the second edge;
at least two spaced apart second notches that each extend from the second edge in a direction toward the first edge;
at least one first fastener receiving hole defined adjacent to one of the at least two spaced apart first notches; and
at least one second fastener receiving hole defined adjacent to one of the at least two spaced apart second notches.

2. The printed circuit board of claim 1 wherein the at least two spaced apart first notches are each positioned parallel to one another.

3. The printed circuit board of claim 1 wherein the at least two spaced apart second notches are each positioned parallel to one another.

4. The printed circuit board of claim 1 wherein one of the at least two spaced apart first notches and one of the at least two spaced apart second notches both extend along a common first centerline.

5. The printed circuit board of claim 1 wherein one of the at least two spaced apart first notches and one of the at least two spaced apart second notches both extend along a first common centerline and another one of the at least two spaced apart first notches and another one of the at least two spaced apart second notches both extend along a second common centerline.

6. The printed circuit board of claim 5 wherein the first common centerline and the second common centerline extend parallel to one another.

7. The printed circuit board of claim 1 further comprising a first group of electrical conductor pads positioned along the first edge.

8. The printed circuit board of claim 1 further comprising a second group of electrical conductor pads positioned along the second edge.

9. The printed circuit board of claim 1 wherein the first fastener receiving hole and the second fastener receiving hole line on a common centerline.

10. The printed circuit board of claim 1 wherein at least one of the first fastener receiving hole and/or the second fastener receiving hole are completely closed.

11. The printed circuit board of claim 1 wherein the first fastener receiving hole and the second fastener receiving hole do not receive a passive or active latch.

12. The printed circuit board of claim 1 wherein the printed circuit board is symmetrical with respect to a centerline that perpendicularly intersects both the third and fourth edges.

13. The printed circuit board of claim 1 wherein the printed circuit board is symmetrical with respect to a centerline that perpendicularly intersects both the first and second edges.

14. The printed circuit board of claim 1 further comprising at least one third fastener receiving hole defined adjacent to one of the at least two spaced apart first notches.

15. The printed circuit board of claim 14 wherein the first fastener receiving hole and the third fastener receiving hole are positioned on the same side of the at least two spaced apart first notches.

16. The printed circuit board of claim 14 wherein the first fastener receiving hole and the third fastener receiving hole line on a common centerline.

17. The printed circuit board of claim 1 further comprising at least one fourth fastener receiving hole defined adjacent to one of the at least two spaced apart second notches.

18. The printed circuit board of claim 17 wherein the second fastener receiving hole and the fourth fastener receiving hole are positioned on the same side of the at least two spaced apart second notches.

19.-29. (canceled)

30. A printed circuit board comprising:
a planar body having a middle body portion, a first fastener portion, and a second fastener portion, and wherein the planar body includes a first edge and an opposed second edge;
wherein the first fastener portion includes one or more first fastener receiving holes;
wherein the second fastener portion includes one or more second fastener receiving holes;
a first bridge portion connecting the first fastener portion to a first side of the middle body portion defined by first opposing notches; and
a second bridge portion connecting the second fastener portion to a second side opposing the first side of the middle body portion defined by second opposing notches.

31-42. (canceled)

43. A method of assembling a mezzanine connector system comprising the steps of:
providing a first PCB having at least one first connector housing extending along a first plane and a first pair of apertures in different planes offset and parallel to the first plane;
providing a second PCB having at least one second connector housing extending along the first plane and a first pair of pins in different planes offset and parallel to the first plane; and
coupling the first PCB to the second PCB with a printed circuit board having opposing receptacles configured to receive the first pair of pins and engage the first pair of apertures, respectively.

44-76. (canceled)
